(19) United States
(12) Patent Application Publication
(10) Pub. No.: US 2012/0313157 A1
(43) Pub. Date: Dec. 13, 2012

(54) DRAM CELL HAVING BURIED BIT LINE AND MANUFACTURING METHOD THEREOF

(75) Inventors: TAH-TE SHIH, TAIPEI (TW); CHUNG-YUAN LEE, TAOYUAN COUNTY (TW); TSUNG-CHENG YANG, TAICHUNG CITY (TW)

(73) Assignee: INOTERA MEMORIES, INC., TAOYUAN COUNTY (TW)

(21) Appl. No.: 13/185,547

(22) Filed: Jul. 19, 2011

(30) Foreign Application Priority Data
Jun. 8, 2011 (TW) 100119995

(51) Int. Cl. H01L 27/108; H01L 21/20

(52) U.S. Cl. 257/301; 438/386; 257/E27.084; 257/E21.09

(57) ABSTRACT

A dram cell having buried bit line includes a substrate having fin structures thereon, a plurality of deep trenches in the substrate, a buried stripe, a plurality of word lines formed on the substrate and a plurality of capacitors formed on the fin structures. Each of the deep trenches is arranged between two adjacent fin structures. Each of the deep trenches has a metal layer and a poly-silicon layer thereinside to define a buried bit line. The buried stripe is formed in the substrate and next to each of the deep trenches. The bit line is electrically connected to the corresponding fin structure via the buried stripe. The word lines are alternatively arranged with the bit lines, and each of the word lines are disposed cross on the fin structures to construct double gate structures.

### BACKGROUND OF THE INVENTION

1. Field of the Invention

The present invention relates to a dram cell and a manufacturing method thereof. In particular, the present invention relates to a dram cell having buried bit line and a manufacturing method thereof.

2. Description of Related Art

For reducing device size, the channel length of the device has been narrowed. Thus, hot carrier effect may cause effluence to the device performance. Contrary to the reduced device size, the operation voltage is still high to result in a traverse electric filed. For example, when the channel of the transistor is less than 2 um, the reliability of the device may be decreased due to the hot carrier effect.

Many methods have been developed to solve the hot carrier effect in narrowed device, for example, recess cell array transistors (RCAT) and sphere-shaped recess cell array transistors (SRCAT). However, the developed methods are too complex.

On the other hand, a method named as “lightly doped drain” (LDD) has been developed to overcome the hot carrier effect. However, it is more difficult to manufacture the structure of the lightly doped drain when the channel length of the device of peripheral circuit area is narrowed less than 0.2 um. Now, by adjusting the width of single spacer, the size of the doped area is controlled. The problem is that the width of single spacer cannot be precisely controlled; thus the reliability of the device is lower.

### SUMMARY OF THE INVENTION

One object of the instant disclosure is providing a dram cell having buried bit line and a manufacturing method thereof. The dram cell has buried bit line formed inside the substrate and the manufacturing method is optimized. The double gate is in conjunction with the buried bit lines to improve the device performance. In addition, the size of the device can be reduced.

The instant disclosure provides a dram cell having buried bit line comprising: a substrate having fin structures thereon; a plurality of deep trenches in the substrate, each of the deep trenches being arranged between two adjacent fin structures, each of the deep trenches having a metal layer and a poly-silicon layer thereinside to define a buried bit line; a buried stripe formed in the substrate and next to each of the deep trenches, the bit line being electrically connected to the corresponding fin structure via the buried stripe; a plurality of word lines formed on the substrate, the word lines being alternatively arranged with the bit lines, each of the word lines disposed cross on the fin structures to construct double gate structures; and a plurality of capacitors formed on the fin structures.

The manufacturing method for a dram cell having buried bit line, comprising the following steps: providing a substrate having fin structures thereon; forming a plurality of deep trenches in the substrate, each of the deep trenches being arranged between two adjacent fin structures; forming a metal layer and a poly-silicon layer in each of the deep trenches to define a buried bit line; forming a buried stripe in the substrate and next to each of the deep trenches, the bit line being electrically connected to the corresponding fin structure via the buried stripe; forming a plurality of word lines alternatively arranged with the bit lines, and forming a plurality of capacitors on the fin structures.

By adjusting the layout of the bit lines and the capacitors, the foot print area can be reduced. In addition, the double gate can improve the performance of the device even when the size thereof is shrunk.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

FIG. 1 shows the dram cell having buried bit line of the instant disclosure.

FIG. 2 shows a side view of the dram cell having buried bit line of the instant disclosure.

FIG. 3 shows a perspective view of the dram cell having buried bit line of the instant disclosure.

### DETAILED DESCRIPTION OF THE PREFERRED EMBODIMENTS

The present invention provides a dram (dynamic random access memory) cell having buried bit line and manufacturing method thereof. By using the double gate structure of the instant disclosure, the properties of the manufactured device are improved, especially for drain induction barrier lower effect (DIBL) of FET or sub-threshold swing. Therefore, the size of the dram cell may be reduced. Furthermore, because of the buried bit lines, the word lines, bit lines and active areas are substantially located on the same surface, the surface is more planar for performing processes thereon. For example, the planar surface is suitable for the manufacturing procedure of the double gate.

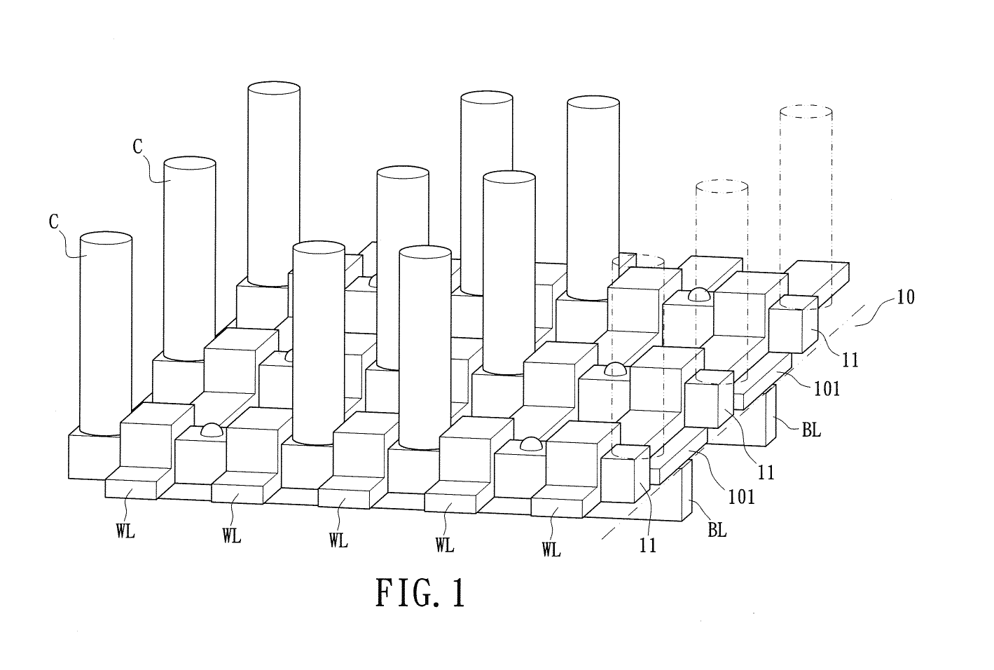

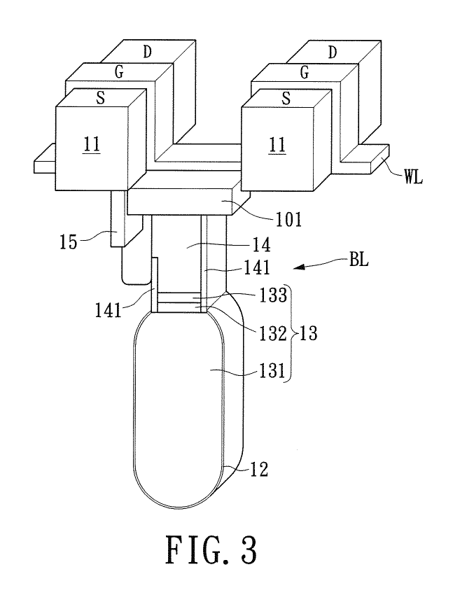

Please refer to FIGS. 1 to 3; the manufacturing method of the instant disclosure at least has the following steps.

Step 1 is providing a substrate 10 which has a plurality of fin structures 11 thereon. In the exemplary embodiment, a Si substrate is etched or produced in similar methods to form the fin structures 11 of Si material. Each fin structure 11 can be an active area, and source “S” and drain “D” are defined in the fin structure 11.

Step 2 is forming a plurality of deep trenches 12 in the substrate 10. For example, a wet etch method which is named as “bottle etch” may be applied for forming the deep trenches 12 in the substrate 10. Each formed deep trench 12 is arranged between two adjacent fin structures 11 and the deep trenches 12 are used to define the bit lines “BL”. In further detail, a mask layer 111 is deposited on the sides of each fin structure 11, for example the mask layer 111 may be spacer structure of silicon nitride. The mask layer 111 is used to define the position and opening size of the deep trench 12 (i.e., the bit lines “BL”). Then, the wet etch is used to remove the material between the mask layers 111 so as to form the deep trench 12 arranged between two adjacent fin structures 11.

Step 3 is forming a metal layer 13 and a poly-silicon layer 14 in each deep trench 12 to define a buried bit line “BL”. The bit line “BL” of a dram cell is formed in this step. In the exemplary embodiment, a W (tungsten) layer 131, a WN (tungsten nitride) layer 132 and a Ti (titanium) layer 133 are deposited in the deep trench 12 by metal deposition methods so as to form the metal layer 13. Preferably, the side walls of the deep trench 12 have a Ti/TiN (titanium/titanium nitride) layer corresponding to the metal layer 13. In other words, the Ti/TiN layer is formed on the bottom side walls of the deep trench 12.

Then, a poly crystal material fills in the deep trench 12 to form the poly-silicon layer 14 on the metal layer 13. Preferably, the side walls of the deep trench 12 have an insulating layer 141 corresponding to the poly-silicon layer 14. For example, silicon nitride materials are deposited on the top side walls of the deep trench 12 as the insulating layer 141 before the formation of the poly-silicon layer 14. The insulating layer 141 formed on one of the side walls of the deep trench 12 is etched for forming an exposed portion. The exposed portion may be used to diffuse the doped ions of the poly-silicon layer 14. After forming the exposed portion, the poly crystal material fills in the deep trench 12 to form the poly-silicon layer 14.

Step 5 is forming a buried stripe 15 in the substrate 10 and next to each of the deep trenches 12. In detail, the doped ions of the poly-silicon layer 14 diffuse toward the outside of the deep trench 12 through the exposed portion of the insulating layer 141 to form the buried stripe 15. The buried stripe 15 is electrically connected between the bit line “BL” and the corresponding fin structure 11. In further detail, the buried stripe 15 is electrically connected between the bit line “BL” and the source “S” and the drain “D” of the corresponding fin structure 11 (i.e., the active area).

In addition, the manufacturing method further includes a step of forming a plurality of word lines “WL” alternatively arranged with the bit lines “BL” on the substrate 10 and a step of forming capacitors “C” on the fin structures 11. The word line “WL” climbs cross on the fin structures 11 so that the double gate “G” is formed on the side surfaces of the fin structures 11. Moreover, the substrate 10 has a STI (shallow trench isolation) structure 101 for isolating the fin structures 11.

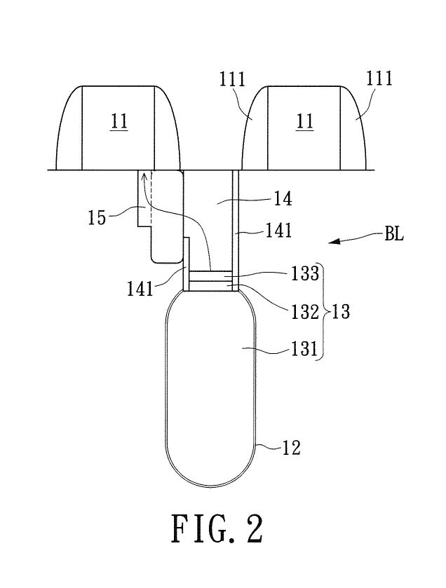

Afterwards, the dram cell of the instant disclosure includes a substrate 10, fin structures 11 on the substrate 10, bit lines “BL” and word lines “WL”. In structural detail, the fin structures 11 elongate in a first direction on the substrate 10. The fin structure 11 can be an active area which has source “S” and drain “D” therein. The bit line “BL” is constructed by the metal layer 13 and the poly-silicon layer 14 in each deep trench 12. Similar with the fin structure 11, the bit line “BL” elongates in the first direction. As shown in FIG. 2; the bit line “BL” is a buried structure in the substrate 10. The bit line “BL” can connect electrically to the source “S” and the drain “D” of the fin structure 11 via the buried stripe 15. The word lines “WL” are formed on the substrate 10 and elongate in the second direction. Accordingly, the word lines “WL” are alternatively arranged with the bit lines “BL” and the fin structures 11. The word lines “WL” can be formed on the fin structures 11 to construct the double gate “G”.

The double gate of the transistor can be turned on by the word lines “WL” to access the data stored in the capacitors “C”. The bit lines “BL” are connected to the source “S” and the drain “D” of the transistor to read the signals stored in the capacitors “C”.

The present invention at least has the following characteristics.

1. Because of the double gate of the present invention, the drive current of the device may be increased. Therefore, the problem of the low drive current, which is resulted from the reduced ratio between channel length and channel width can be solved.

2. The dram cell of the present invention has properties of low DIBL and low off state current. In addition, the problem of sub-threshold swing is solved. Due to the above-mentioned problems which occur when the device size is reduced are solved, the device size of the present invention can be reduced to 20 nm.

3. The method for manufacturing fin structures introduced in the instant disclosure is compatible with the CMOS processes.

The description above only illustrates specific embodiments and examples of the present invention. The present invention should therefore cover various modifications and variations made to the herein-described structure and operations of the present invention, provided they fall within the scope of the present invention as defined in the following appended claims.

What is claimed is:

1. A dram cell having buried bit line comprising:
a substrate having fin structures thereon;
a plurality of deep trenches in the substrate, each of the deep trenches being arranged between two adjacent fin structures, each of the deep trenches having a metal layer and a poly-silicon layer thereinside to define a buried bit line;
a buried stripe formed in the substrate and next to each of the deep trenches, the bit line being electrically connected to the corresponding fin structure via the buried stripe;
a plurality of word lines formed on the substrate, the word lines being alternatively arranged with the bit lines, each of the word lines disposed cross on the fin structures to construct double gate structures; and
a plurality of capacitors formed on the fin structures.

2. The dram cell as claimed in claim 1, wherein each of the deep trenches has an insulating layer on two walls thereof corresponding to the poly-silicon layer, the insulating layer formed on one of the two walls has an exposed portion, the buried stripe corresponds to the exposed portion to connect the bit line to the corresponding fin structure.

3. The dram cell as claimed in claim 2, wherein each of the fin structure is an active area.

4. The dram cell as claimed in claim 3, wherein the bit line connects to a source and the drain of the active area via the buried stripe.

5. The dram cell as claimed in claim 2, wherein the metal layer includes a W layer, a WN layer and a Ti layer.

6. The dram cell as claimed in claim 2, wherein the insulating layer is a SiN layer.

7. A manufacturing method for a dram cell having buried bit line, comprising the following steps:
providing a substrate having fin structures thereon;
forming a plurality of deep trenches in the substrate, each of the deep trenches being arranged between two adjacent fin structures;
forming a metal layer and a poly-silicon layer in each of the deep trenches to define a buried bit line;
forming a buried stripe in the substrate and next to each of the deep trenches, the bit line being electrically connected to the corresponding fin structure via the buried stripe;
forming a plurality of word lines alternatively arranged with the bit lines, and forming a plurality of capacitors on the fin structures.

8. The manufacturing method as claimed in claim 7, wherein in the step of forming a metal layer and a poly-silicon layer, further comprising a step of forming an insulating layer on two walls of each of the deep trenches corresponding to the poly-silicon layer, and an etching step for forming an exposed portion on the insulating layer formed on one of the two walls.

9. The manufacturing method as claimed in claim 8, further comprising a step forming a hard mask layer on sides of each of the fin structures before the step of forming a plurality of deep trenches in the substrate.

10. The manufacturing method as claimed in claim 7, wherein in the step of forming a metal layer includes steps of forming a W layer, a WN layer and a Ti layer.
